(19) United States
(12) Patent Application Publication
(10) Pub. No.: US 2007/0018728 A1
(43) Pub. Date: Jan. 25, 2007

(54) Method and system for providing multi-carrier synthesis

(76) Inventor: Oleksandr Volkov, Cork (IE)

Correspondence Address: ARRIS INTERNATIONAL, INC, 3871 LAKEFIELD DRIVE, SUWANEE, GA, 30024, US

(21) Appl. No.: 11/492,640

(22) Filed: Jul. 25, 2006

Related U.S. Application Data
(60) Provisional application No. 60/702,326, filed on Jul. 25, 2005.

(51) Int. Cl. H03F 3/45

(52) U.S. Cl. 330/254

(57) ABSTRACT

A nyquist filter upsamples multiple input symbol streams. Separate first stage branch low-pass filters further upsample the streams. A tap at each filter has a delay different from the other branch(s) to extract symbols from different streams. The outputs of the low-pass filters are additively combined in one branch and are subtracted in another. The outputs from the additive and subtraction combiners are provided to corresponding multipliers that multiply by real cosine and sine functions, respectively. The outputs of the multipliers are alternatingly combined (alternates during every clock cycle between addition and subtraction) at a first stage combiner. A second stage processes the output of the first stage combiner similarly to processing performed by the first stage. The output of the second stage alternating combiner is the input symbol streams in baseband with carriers spaced apart by a predetermined frequency based on the real function used by the real multipliers.

### CROSS REFERENCE TO RELATED APPLICATION

This application priority under 35 U.S.C. 119(e) to U.S. provisional patent application No. 60/702,326 entitled “Efficient multi-carrier synthesis,” which was filed Jul. 25, 2005, and is incorporated herein by reference in its entirety.

### FIELD OF THE INVENTION

The present invention relates generally to communication devices, and more particularly to combining and transmitting of multiple modulated signals.

### BACKGROUND

Cable data systems are used to allow cable TV subscribers use the Hybrid-Fiber-Coax network as a communication link between their home networks and the Internet. As a result, computer information (Internet Protocol packets) can be transmitted across the Hybrid-Fiber-Coax network between home computers and the Internet. The DOCSIS specification (defined by CableLabs) specifies the set of protocols that must be used to effect a data transfer across the Hybrid-Fiber-Coax network. Two fundamental pieces of equipment permit this data transfer: a cable modem (CM) which is positioned in the subscriber's home, and a Cable Modem Termination System (CMTS) which is positioned in the head end of the cable TV company.

In addition to data traffic, subscribers are more and more obtaining telephony voice services over networks other than the traditional public switched telephony network (“PSTN”). A multiple services operator (“MSO”) may provide such telephony services, in addition to data over cable service via DOCSIS. For example, CableLabs has established the PacketCable standard for providing telephony services over cable. A subscriber typically has a device that includes a DOCSIS cable modem for transmitting and receiving data and a media terminal adaptor (“MTA”) for processing voice traffic for transmission and reception over cable.

As the amount of bandwidth used between the CMTS and the cable modems increases due to increasing data rates of signals, proposals have been made that multiple channels between the CMTS and cable modems be bonded together to form in essence a ‘super-channel’ that can better satisfy the demand for high definition video, digital voice signals and data signals. Proposals have been made to adopt a new DOCSIS standard that couples, or bonds, channels together to effectively create a larger ‘pipe’, or data carrying medium.

A classic approach is to implement the block diagram as shown in FIG. 1, typically using field programmable gate array (“FPGA”) as known in the art. The classic approach implements a four-carrier synthesizer system 2. Four input signals 4 are shown being input into four separate and corresponding upsampling and Nyquist filtering blocks 6. Signals 4 are outputs from four separate quadrature amplitude modulation (“QAM”) mappers having a sample rate equal to the modulation rate as known in the art. From the Nyquist filters 6, the filtered signals are each passed to upsampling and low pass filter blocks 8. It will be appreciated that the upsampling at blocks 6 is two time upsampling and blocks 8 are four-times upsampling. From the low pass filter blocks 8, the filtered signals are passed on to complex multipliers 10, that multiply the incoming signals from blocks 8 with an exponential expression as shown in the figure, where b is a coefficient that corresponds to frequency spacing between the carrier of signals 4. The output of complex multiplier 10 is passed on to summing block 12, which outputs the combined/synthesized signal. It will be appreciated that the clock signal in the example illustrated in is at least eight times the symbol rate of any of the incoming signals 4, since blocks 6 upsample by a factor of two and then blocks 8 upsample by a factor of four.

While system 2 performs the desired objective, it performs multiple complex multiplications as well as many operational blocks. Therefore, there is a need for a method and system that performs the functionality of the classic approach shown in FIG. 1 using fewer blocks that perform simpler operations.

### SUMMARY

A system receives a communication signal that comprises multiple streams of QAM symbols and synthesizes them into bound baseband signals. The multiple bound baseband signals have different carrier frequencies. The system includes a means for receiving, filtering and upsampling the time-distributed multi-channel signals from a front end input and providing the filtered signals at a front end output. This means may be a Nyquist raised-cosine filter.

A first stage means further upsamples the filtered signals from the front end output and provides the first stage upsampled signals at first stage upsampled branch outputs, a branch carrying data that may correspond to more than one QAM stream. A plurality of first stage branch means processes the signals from the first stage upsampled branch outputs and provides the processed signals at first stage processed branch signal outputs. A first stage means for combining the processed first stage branch signals combines data from the first stage processed branch signal outputs into a first stage composite signal and provides the first stage composite signal at a first stage composite output.

A second stage means for upsampling upsamples the first stage composite signal and provides the second stage upsampled signals at second stage upsampled branch outputs. A plurality of second stage branch means for processing processes the signals from the second stage upsampled branch outputs and provides the processed signals at second stage processed branch signal outputs. Second stage means for combining signals combines the processed second stage branch signals from the second stage processed branch signal outputs into a second stage composite signal and providing the second stage composite signal at a second stage composite output. The first stage means for combining and the second stage means for combining include means for alternating between adding and subtracting branch signals during successive system clock cycles.

The branch means for processing may include means for low-pass filtering the signal received from the front end output at a low pass filtering input, each low-pass filtering means having an output. Intermediate combining means combines the signals from the low-pass filtering means' output with the outputs of at least one other first low pass filtering means' output, the at least one other low pass filtering means corresponding to at least one other branch. The intermediate combining means provides combined signals at an intermediate combined signal output. The intermediate combining means may be coupled to the output of the low-pass filtering means and the output of at least one other low-pass filtering means corresponding to another branch.

The branch processing means for the first stage and the branch means for the second stage are similar except that a first stage branch means receives its input from the output of the front end stage and a second stage branch receives its input from the output of the first stage combining means.

Each low-pass filtering means' input is delayed a predetermined number of clock cycles with respect to the other low-pass filtering means. A branch means also includes means for multiplying the signal output from the first-stage intermediate combining means with a real function and for providing the product of the multiplier to the first stage means for combining processed first stage branch signals.

An intermediate branch combining means in one branch adds its inputs together and another intermediate branch combining means in the same stage subtracts its inputs. The first and second stage combining means both alternate between adding their inputs together and subtracting their inputs every other system clock cycle.

### BRIEF DESCRIPTION OF THE DRAWINGS

FIG. 1 illustrates a classic approach to synthesizing multiple streams into base band.

FIG. 2 illustrates an improved approach to synthesizing multiple streams into base band.

FIG. 3 illustrates an optimized approach to synthesizing multiple streams into base band.

FIG. 4 illustrates a timing diagram of an input signal after nyquist filtering.

FIG. 5 illustrates branch input timing diagrams and results after upsampling.

FIG. 6 illustrates a timing diagram of the output of the first stage alternating combiner.

FIG. 7 illustrates a graph of the signal that is output from the first stage alternating combiner.

FIG. 8 illustrates a graph of the signal that is output from the second stage alternating combiner.

### DETAILED DESCRIPTION

As a preliminary matter, it will be readily understood by those persons skilled in the art that the present invention is susceptible of broad utility and application. Many methods, embodiments and adaptations of the present invention other than those herein described, as well as many variations, modifications, and equivalent arrangements, will be apparent from or reasonably suggested by the present invention and the following description thereof, without departing from the substance or scope of the present invention.

Accordingly, while the present invention has been described herein in detail in relation to preferred embodiments, it is to be understood that this disclosure is only illustrative and exemplary of the present invention and is made merely for the purposes of providing a full and enabling disclosure of the invention. This disclosure is not intended nor is to be construed to limit the present invention or otherwise to exclude other embodiments, adaptations, variations, modifications and equivalent arrangements, the present invention being limited only by the claims appended hereto and the equivalents thereof.

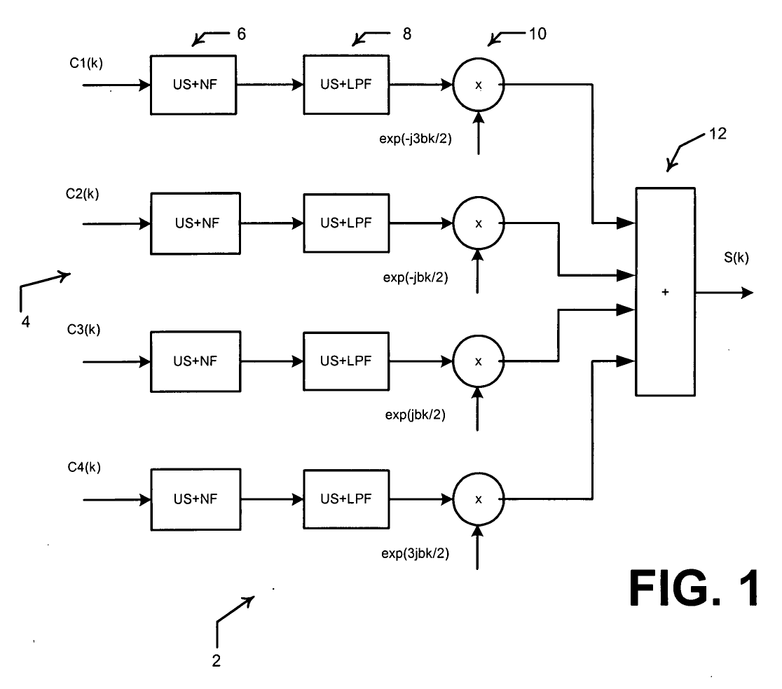

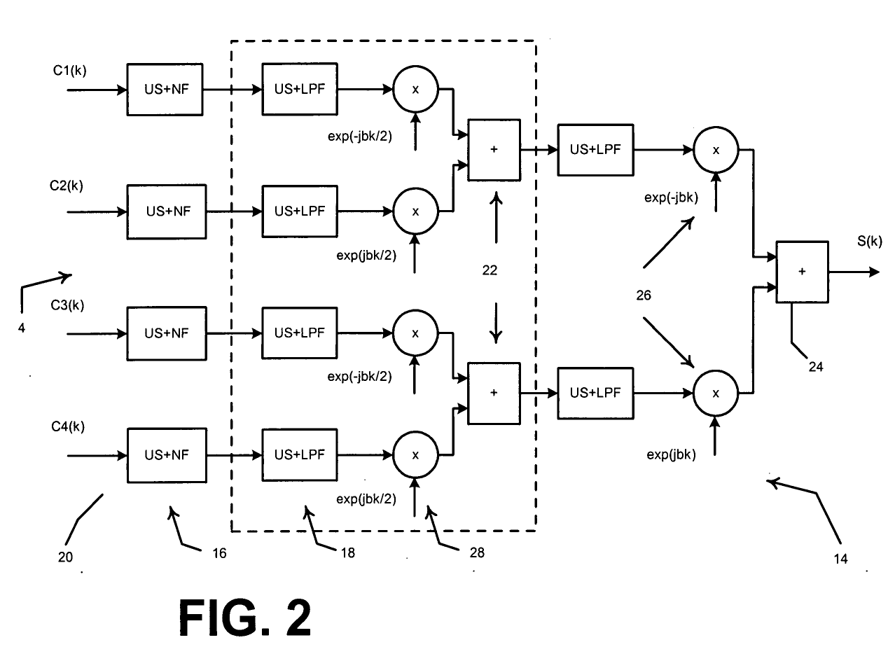

Turning now to FIG. 2, a system 14 that is a simplified version of system 2 shown in FIG. 1 is shown. However, as opposed to the low pass filter blocks 8 in FIG. 1, the nyquist filter blocks 16 provide the channel signals to low pass filter blocks 18, which perform two-times upsampling rather than four-times upsampling as performed by the low pass filters in FIG. 1. Notwithstanding that each upsampling block may be a two-times upsampling, there are more upsampling blocks shown in system 14 than in system 2 shown in reference to FIG. 1. This reduces costs because two-times upsampling is less expensive than four-times upsampling. Unfortunately, system 14 shown in FIG. 2 employs more blocks than system 2 shown in FIG. 1. Moreover, system 14 uses 10 different blocks that perform upsampling for the four-channel system shown. It will be appreciated that more multi-channel signals that are input to either system viewed from the left of the respective figure will typically use correspondingly more component blocks to process the extra channel signals. Other than the up-sampling being less at the nyquist filtering blocks 16 with respect to blocks 6 in FIG. 1, the components enclosed by the box formed by broken line 20 in FIG. 2 are similar. Simpler first stage combiners 22 and second/final stage combiner 24, while greater in number than the single combiner 12 in FIG. 1, reduce costs, however, more FPGA resources, represented by blocks on the schematic, are used and more power is used to operate the circuitry. Likewise, complex multipliers 26 and second stage low pass filters and upsamplers contribute to space usage, power usage and heat production. Thus, although system 14 illustrated in FIG. 2 is an upgrade with respect to system 2 illustrated in FIG. 1, there are more components used than in system 2. Thus, further optimization may be desired.

It will be appreciated that the output of each combiner 22 is double the bandwidth of the carrier of one of the inputs 4, but is half of the output from combiner 24. Thus, two of the four first stage branches between inputs 4 and combiners 22 could be replaced by a single branch operating at twice the carrier frequency of one of the single branches shown in FIG. 2 to provide an output from combiner 24 having the same output bandwidth as from combiner 24 shown in FIG. 2.

In addition, further simplification may be achieved by changing the multiplication and addition operations performed by first stage complex multipliers 28. For example, the output of either of the combiners 22 may be expressed as

$$\begin{matrix}{S}_{1} = [ {I}_{1} + {jQ}_{1} ] exp ( - j bk / 2 ) + [ {I}_{2} + j {Q}_{2} ] exp ( j bk / 2 ) \\ = ( {I}_{1} + {I}_{2} ) cos ( bk / 2 ) + ( {Q}_{1} - {Q}_{2} ) sin ( bk / 2 ) + \\ j [ ( {Q}_{1} + {Q}_{2} ) cos ( bk / 2 ) - ( {I}_{1} - {I}_{2} ) sin ( bk / 2 ) ] .\end{matrix} \qquad Eq . 1$$

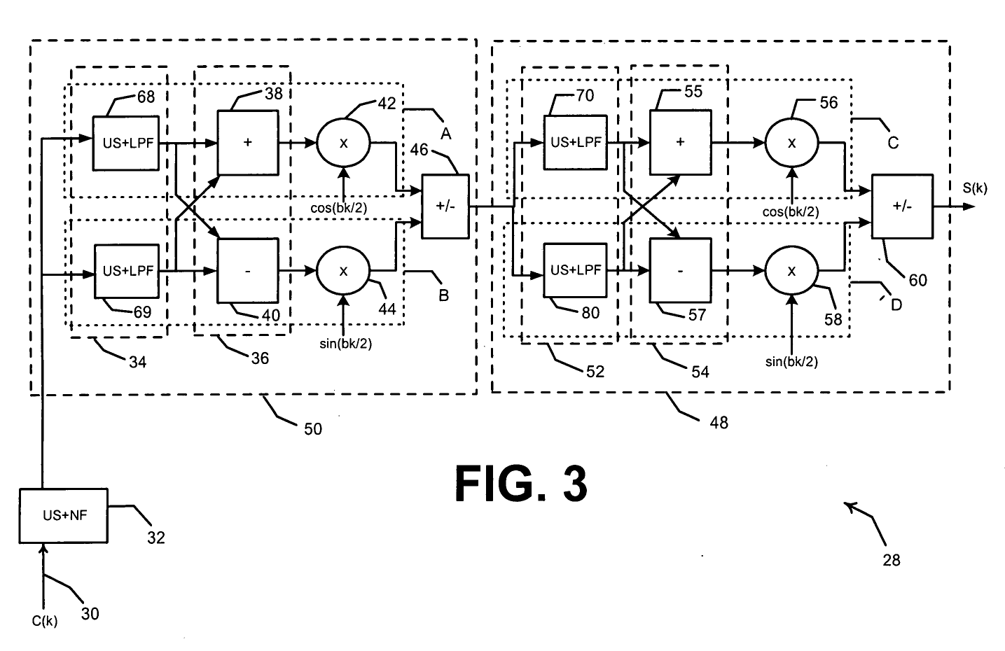

From Eq. 1 it can be seen that the real and imaginary components of signal S₁ can be generated by a single combiner instead of the two combiners 22 shown in FIG. 2. To facilitate this, the operation of the combiner component block alternates between addition and subtraction every other system clock cycle. To maintain bandwidth throughput of a signal, the clock speed in doubled, since each clock signal at the alternating combining block causes an output of only a portion of a signal sample. The operation of the alternating combining component may be represented by:
S=(X₁+X₂)cos(bk/2)±(Y₁−Y₂)sin(bk/2) Eq. 2

where alternating combiner inputs that receive component signals from complex multipliers are represented by X₁,X₂ and Y₁,Y₂, which may be I,Q coefficient pairs of symbols from signals C1(k) and C2(k) respectively, as shown by the input signals in FIG. 3. Although the clock speed is doubled so that the alternating combiner does not halve signal throughput bandwidth, the number of processing components represented by function blocks in the figures is reduced.

A block diagram of a multi signal synthesizer using a means for alternating between adding and subtracting component signals for each successive clock cycle of the system is shown in FIG. 3. It will be appreciated that blocks in the figure represent typically electrical circuitry, which may be implemented with discrete components, application specific integrated circuits (“ASIC”), or preferably using field programmable gate arrays (“FPGA”) as known in the art. In FIG. 3, system 28 reduces the number of components used with respect to systems 2 and 14 shown in FIGS. 1 and 2 respectively. Instead of having four separate channels being input to four separate up-sampling/nyquist filter blocks as in FIGS. 1 and 2, a plurality of time-distributed multi-channel signals, which have been combined into a single signal 30 are input to up-sampling/nyquist filter block 32. It will be appreciated that each of the individual signals that make up signal 30 are typically modulated signals having carriers that are spaced a predetermined amount apart. For example, the individual signals may be Quadrature Amplitude Modulation (“QAM”) signals that each have a bandwidth spectrum span of 6 MHz. Thus, the minimum spacing between channels would be approximately 6 MHZ, as known in the art, for signals of adjacent channels in a DOCSIS system, for example.

From the output of Nyquist filter block 32, the signal is split into branch signals that correspond to first stage branches A and B and sent to corresponding up-sample/low pass filters 34. For purposes of discussion, upsample/nyquist filter 32 and components that may be associated therewith and means for splitting the signal output there from are referred to as a front end stage of system 28. From the front end, the split signals are processed by filter blocks 34, the input to each filter block having a delay of a predetermined number of clock cycles that may be based on the number of signals included in signal 30. After processing, the branch signals are fed to combiners 36. Combiners 36 are similar to one another in that they combine two branch signals received at two separate inputs.

However, combiner 38 performs an addition operation on the signals received at its two inputs. Combiner 40 performs a subtraction operation on the signals received at its two inputs. The outputs from combiners 38 and 40 are input to multipliers 42 and 44, respectively. Multiplier 42 multiplies the signal received from combiner 38 with a cosine function and multiplier 44 multiplies the signal received from combiner 40 with a sine function. Both sine and cosine functions are functions of bk/2, where b is a coefficient that represents the frequency spacing between the multiple signals combined into signal stream 30. It will be appreciated that the multiplier sine and cosine functions that are input at the bottom of multipliers 42 and 44 as shown in the figure are real functions, as contrasted with the complex functions that are input to the bottom of complex multipliers 10 and 28 shown in FIGS. 1 and 2 respectively. This simplifies the design of the FPGA that implements the multipliers.

The outputs of multipliers 42 and 44 are input into first stage alternating combiner 46, which alternatingly combines signals presented at its input. Alternating combiner 46 alternatingly combines signals by adding signals presented at its inputs during one system clock cycle, and by subtracting signals presented at its inputs during the next clock cycle. During a clock cycle alternating combiner 46 may add signals, the next cycle after that it would subtract again, the next clock cycle the combiner would add again and so on. Accordingly, every other clock cycle alternating combiner 46 performs a subtraction instead of addition of signals presented at its inputs and provides the result at an output referred to as a composite output.

The composite output of alternating combiner 46 is split and fed to a second stage 48, which is similar to the first stage 50. The split signals from alternating combiner 46 are fed to second stage low pass filters 52, which perform the same functions as first stage low pass filters 34. Similar to filters 34, which feed their outputs to first stage intermediate combiners 36 and 38, second stage low pass filters 52 feed their outputs to second stage intermediate combiners 54. Like first stage intermediate combiners 38 and 40, which perform addition and subtraction, respectively, second stage branch C combiner 55 and branch D combiner 57 perform addition and subtraction operations, respectively. After the signals have been processed by combiners 54, the respective signals are forwarded to branch C multiplier 56 and branch D multiplier 58, which perform cosine and sine multiply operations like multipliers 42 and 44, respectively. The outputs from multipliers 56 and 58 are combined at second stage alternating combiner 60, which performs operations similarly to alternating combiner 46.

It will be appreciated that if system 28 is properly timed, first stage processing functions and second stage processing functions may be implemented using the same physical components for corresponding first and second stage components. For example, system 28 that processes four channels may use the same FPGA ‘real estate’ for both first and second stage processing functions. In such an embodiment, the system clock speed would be doubled and a few extra components, such as, for example, a switching function at the input to the stage(s) function blocks could be used to differentiate between symbol stream input to the system and the output of the first stage which is being fed back to the same point.

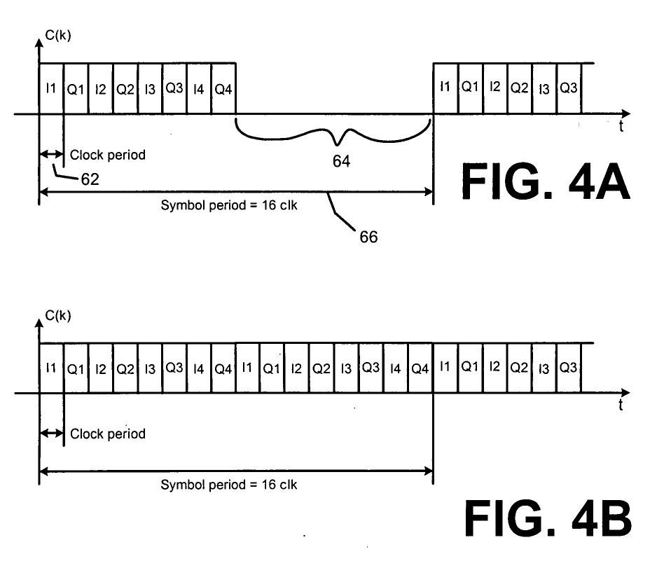

To further illustrate operation of the synthesizer, a set of timing diagrams are shown below. In FIGS. 4A and 4B, the input signal(s) C(k) are shown versus time. I1 and Q1 correspond to C1(k), as shown in FIGS. 1 and 2; I2 and Q2 correspond to C2(k); and so on. The width in time of each half symbol equals a clock period 62. To maintain desired signal bandwidth, the data rate of the signal C(k) present at input 30 in FIG. 3 is upsampled by a factor of two in order to accommodate alternating combiners 46 and 60 shown in FIG. 3. Thus, after the first symbol of each of the four signals that comprise C(k) are received, which time period equals eight clock periods, an equal number of blank spaces 64, or a time equal to the first eight clock periods is inserted as shown in FIG. 4A. Thus, the first eight clock periods 62 that correspond to the first symbols of the four signals of C(k) and the following eight spaces, are referred to as a symbol period 66. After symbol period 66 has elapsed, another symbol period begins, during which the next symbol of each of the four C(k) signals and their following blank spaces of time are received. The latter part of symbol period 66 represented by blank spaces 64 is filled with results of the nyquist filtering. This is shown in FIG. 4B, and represents the input signal C(k) after upsampling and nyquist filtering by filter 32 shown in FIG. 3.

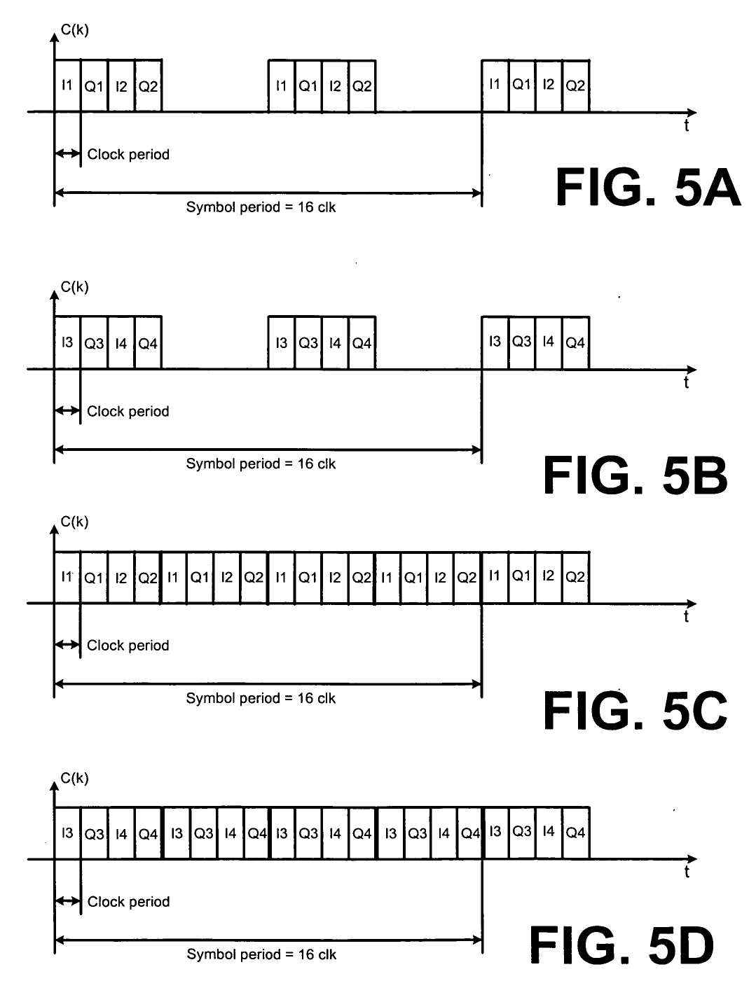

After nyquist filtering by filter 32, the signal C(k) is split to first stage first and second branch inputs at upsampling/low pass filters 34. The taps at filters 34 have a separation delay of four clock cycles between them so that, for example, the first branch input (to first branch) is represented by the timing diagram in FIG. 5A. Accordingly, the input to the second first stage branch is represented by the diagram shown in FIG. 5B. After filtering by filters 68 and 69 shown in FIG. 3, the outputs of the filters are shown for the first branch and second branch of the first stage in FIGS. 5C and 5D, respectively.

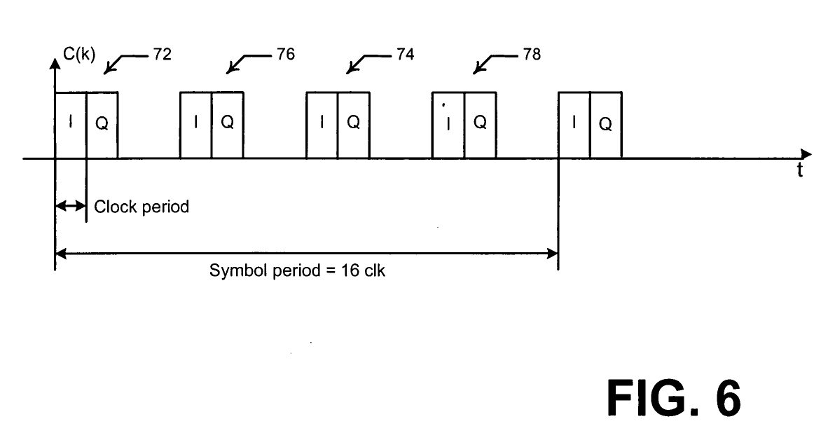

The outputs of filters 68 and 69 are processed according to Eq. 2 given above by combiners 38 and 40, multipliers 42 and 44 and alternating combiner 46. During a given symbol period, Eq. 2 is performed eight times, four times for combining C1=I1+jQ1 with C3=I3+jQ3 and four times for combining C2=I2+jQ2 with C4=I4+jQ4. The resultant signal(s) from alternating combiner 46 is/are forwarded to the inputs of second stage low pass filters 52, as shown in FIG. 3. Filters 52 are separated by a two clock period delay, similar to the four clock period delay at the inputs to filters 68 and 69 discussed above. Thus, the information input to the second stage branch C filter 70 are represented by information in clock period blocks 72 and 74 and the inputs to second stage branch D low pass filter 80 are represented by information in clock period blocks 76 and 78 shown in FIG. 6. The signals present at the second stage first and second branch low pass filters (70 and 80, respectively) are described below by Eqs. 3 and 4, respectively.
Z₁₌(I₁+I₃)cos(bk/2)+(Q₁−Q₃)sin(bk/2)+j[(Q₁+Q₃)cos(bk/2)−(I₁−I₃)sin(bk/2)] Eq. 3
Z₂₌(I₂+I₄)cos(bk/2)+(Q₂−Q₄)sin(bk/2)+j[(Q₂+Q₄)cos(bk/2)−(I₂−I₄)sin(bk/2)] Eq. 4.

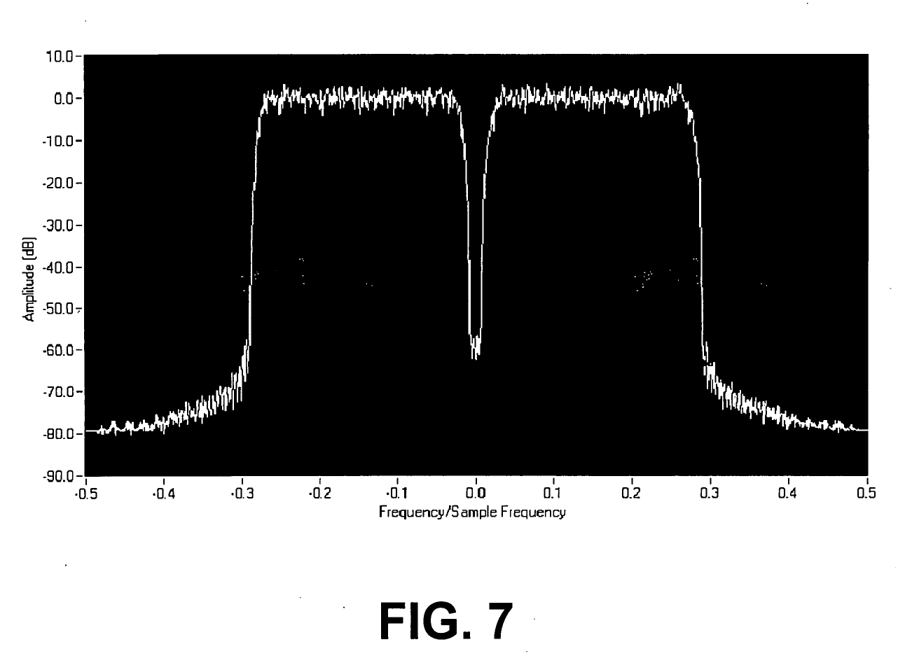

Each combined signal (comprising Z₁ and Z₂) is a double-carrier signal having a spectrum as shown in FIG. 7. The center frequency of each signal ‘plateau’ carrier is determined by coefficient b, which defines the spacing between adjacent channel carrier frequencies. For example, b may be set to equal 6 MHz.

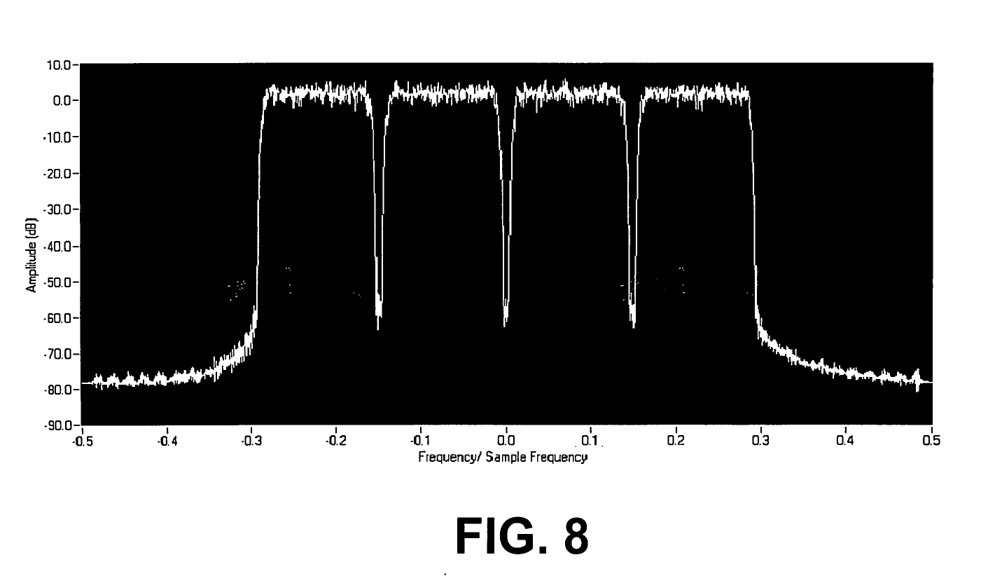

Each second stage low pass filter 52 fills in gaps shown in the timing diagram of FIG. 6, and the combined signal comprising Z₁ and Z₂ is processed by combiners 54, multipliers 56 and 58, and alternating combiner 60, according to Eq. 2, as discussed above. It will be appreciated that when Eq. 2 is applied during the first stage, combiners 38 and 36 are an adder and a subtractor, respectively. Both of combiners 55 and 57 are also an adder and a subtractor, respectively. Thus, during a symbol period, algorithm described by Eq. 2 is performed eight times, four times during the first stage and four times during the second stage. The spectrum of the signal output from alternating combiner 60 shown in FIG. 3 is shown in FIG. 8. The spectrum illustrated in FIG. 8 is also the spectrum S(k) if processing is performed according to the classic approach shown in reference to the diagram in FIG. 1. Thus, the optimized system illustrated in FIG. 3 provides similar functionality as achieved with the classic approach illustrated in FIG. 1.

The classic system approach of FIG. 1 at an 8-symbol rate clock typically uses two 4-polyphase nyquist filters, eight low pass filters that upsample by a factor of 4, sixteen real multipliers and fourteen adders. A similarly functioning classic approach system based on a 16-symbol rate clock would typically use one 8-polyphase nyquist filter, four low pass filters that upsample by a factor of 4, eight real multipliers and seven adders.

However, by using an arrangement as illustrated in FIG. 3, complexity is reduced. The same number, eight, of polyphase nyquist filtering operations are performed per symbol period as with the classic approach. There are four upsampling/low pass filter operations as in the classic approach, but the upsampling factor is two instead of four. Moreover, there are only four multiplier operations as compared to 8 in the classic approach, and the multiply operations performed by the optimized systems shown in FIG. 3 multiply the incoming signal by a real function. It will be appreciated that this increases simplicity in designing an FPGA or an application specific integrated circuit (“ASIC”). Furthermore, there are five adders instead of seven. The system in FIG. 3 typically operates at a clock rate that is sixteen times as fast as the symbol rate of one of the components of C(k).

The number of blocks of the optimised four-channel synthesizer may typically include: one nyquist filter (8-polyphase), which is similar to the classic approach with 16 symbol rates clock. In addition, four low pass filters performing two-times upsampling is used. This is simpler than in the classic approach system using sixteen symbol rates clock. The optimized system also uses four real multipliers instead of the eight real multipliers used in the classic system that operates at a sixteen-symbol-rate clock. Five adder/combiners instead of the seven used in the described classic approach system with 16 symbol rates clock is implemented in the optimized system approach.

It will be appreciated that a larger number of carriers, as compared to the four used herein to describe various aspects, may also be processed according to the aspects. However, some changes with respect to the aspects herein described may be implemented. For example, if eight carriers instead of four were being synthesized together, an overall clock speed of thirty-two cycles per symbol period, instead of sixteen when there are four discrete signals to be synthesized.

Some benefits of the described aspects as compared to the classic approach include fewer block that are implemented in a FPGA or ASIC. Another advantage is that upsampling by a factor of two at the low pass filters is easier to implement in a FPGA than low pass filters that upsample by a factor of four. In addition, fewer busses are used in the described approach as opposed to the classic approach, which is a benefit with respect to designing and implementing FPGA or ASIC routing.

Another advantage is that since the multipliers multiply by a function that is a function of the channel spacing value b, independent control of channel spacing and carrier spectrum is obtained as compared with other types of systems, like OFDM, for example.

It will be appreciated that an aspect illustrating the synthesis of four symbol streams into four corresponding baseband channels is described for clarity. However, more than four symbol streams may be synthesized into a corresponding number of baseband signal channels by following the teaching described herein with appropriate modifications that will be apparent to those skilled in the art. For example, the system clock speed may be increased and additional processing blocks/stages may be used to implement the mathematical reformulation of Eqs. 1 and 2, which could be written to express the relationship of more than the four signals in similar fashion that Eqs. 1 and 2 given above express the relationship between the four input signal streams described above.

These and many other objects and advantages will be readily apparent to one skilled in the art from the foregoing specification when read in conjunction with the appended drawings. It is to be understood that the embodiments herein illustrated are examples only, and that the scope of the invention is to be defined solely by the claims when accorded a full range of equivalents.

What is claimed is:

1. A system for processing a plurality of content signals, comprising:
means for receiving, filtering and upsampling time-distributed multi-channel signals from a front end input and providing the filtered signals at a front end output;
first stage means for upsampling the filtered signals from the front end output and providing the first stage upsampled signals at first stage upsampled branch outputs,
a plurality of first stage branch means for processing the signals from the first stage upsampled branch outputs and providing the processed signals at first stage processed branch signal outputs;
first stage means for combining the processed first stage branch signals from the first stage processed branch signal outputs into a first stage composite signal and providing the first stage composite signal at a first stage composite output;
second stage means for upsampling the first stage composite signal and providing the second stage upsampled signals at second stage upsampled branch outputs;
a plurality of second stage branch means for processing the signals from the second stage upsampled branch outputs and providing the processed signals at second stage processed branch signal outputs;
second stage means for combining the processed second stage branch signals from the second stage processed branch signal outputs into a second stage composite signal and providing the second stage composite signal at a second stage composite output; and
wherein the first stage means for combining and the second stage means for combining include means for alternating between adding and subtracting branch signals during successive system clock cycles.

2. The system of claim 1 wherein the means for receiving and filtering from the front end input includes a nyquist raised-cosine filter.

3. The system of claim 1 wherein each first stage branch means for processing includes:
means for low-pass filtering the signal received from the front end output at a low pass filtering input, each low-pass filtering means having an output;
intermediate combining means for combining the signals from the low-pass filtering means's output with low pass filtering means's outputs of at least one other first stage low pass filtering means corresponding to at least one other branch and providing the combined signals at an intermediate combined signal output, the intermediate combining means being coupled to the output of the low-pass filtering means and the output of at least one other first-stage low-pass filtering means corresponding to another branch; and
means for multiplying the signal from the first-stage intermediate combining means with a real function and for providing the product of the multiplier to the first stage means for combining processed first stage branch signals.

4. The system of claim 3 wherein each of the low-pass filtering means' inputs is delayed a predetermined number of clock cycles with respect to the other low-pass filtering means.

5. The system of claim 3 wherein each second stage branch means for processing includes:
means for low-pass filtering the signal received from the front end output at a low pass filtering input, each low-pass filtering means having an output;
intermediate combining means for combining the signals from the low-pass filtering means' output with low pass filtering means's outputs of at least one other second stage low pass filtering means corresponding to at least one other second stage branch and providing the combined signals at an intermediate combined signal output, the intermediate combining means being coupled to the output of the low-pass filtering means and the output of at least one other second-stage low-pass filtering means corresponding to another second stage branch; and
means for multiplying the signal from the second-stage intermediate combining means with a real function and for providing the product of the multiplier to the second stage means for combining processed second stage branch signals.

6. The system of claim 5 wherein the receiving and filtering means, the first stage low-pass filtering means and the second stage low-pass filtering means include means for upsampling signals received at their inputs.

7. The system of claim 6 wherein the upsampling is two-times upsampling.

8. The system of claim 3 wherein the real function is a function of the spacing of the carrier frequencies of the time-distributed multi-channel signals

9. The system of claim 1 wherein the system is implemented in an FPGA.

10. The system of claim 1 wherein the system is implemented in and ASIC.

11. The system of claim 1 wherein the content signals include streams of QAM symbols.

12. The system of claims 1 wherein first stage means and second stage means are implemented in the same portions of a field programmable gate array.

13. A method for processing a communication signal that includes a plurality of individual content signals, comprising:
step for first stage processing a first group of the plurality of signals;
step for first stage processing another group of the plurality of signals separately from the processing of the first group;
step for alternatingly combining the processed first and second groups of signals into a composite signal that includes a plurality of first stage processed signals;
step for second stage processing a first group of the plurality of first stage processed signals;
step for second stage processing a second group of the plurality of first stage processed signals; and
step for alternatingly combining the first and second group of second stage processed signals into a plurality of baseband signals, wherein each baseband signal corresponds to one of the.

14. The method of claim 13 wherein each of the individual content signals is a stream of QAM symbols.

15. The method of claim 13 wherein the baseband signals have different carrier frequencies.

16. A method for processing a plurality of content signals, comprising:
step for receiving a communication signal that includes time-distributed multi-channel signals;
step for upsampling the communication signal;
step for pulse-shape filtering the communication signal;
step for splitting the communication signal into a plurality of first stage component signals and providing the plurality of first stage component signals to corresponding input taps of a plurality of first stage low-pass filters, each tap having a delay of a predetermined number of clock periods with respect to the other taps;
step for upsampling the first stage component signal at each of the low pass filters;
step for low pass filtering each of the first stage component signals;
step for combining an output of each of the first stage low pass filters with the output of one or more of the other first stage low pass filters into first stage intermediate combined communication signals;
step for multiplying each of the first stage intermediate combined communication signals with a real function; and
step for alternatingly combining the first stage multiplied signals into a final combined first stage signal.

17. The method of claim 16 further comprising:
step for splitting the final combined first stage signal into a plurality of second stage component signals and providing the plurality of second stage component signals to corresponding input taps of a plurality of second stage low-pass filters, each tap having a delay of a predetermined number of clock periods between the other taps;
step for upsampling the second stage component signal at each of the low second stage pass filters;
step for low pass filtering each of the first stage component signals;
step for combining an output of each of the second stage low pass filters with the output of another of the second stage low pass filters into a plurality of second stage intermediate combined communication signals;
step for multiplying each of the second stage intermediate combined communication signals with a signal that is a function of the frequency spacing between the time-distributed multi channel signals into second stage multiplied signals; and
step for combining the second stage multiplied signals into final combined second stage signals.

18. The method of claim 16 wherein the real function is a function of the frequency spacing between the time-distributed multi channel signals.

19. The method of claim 16 wherein the content signals include streams of QAM symbols.

20. The method of claim 16 wherein the final combined second stage signals include multiple baseband signals.

21. The method of claim 20 wherein each of the multiple baseband signals has a carrier frequency that is different from that of the other multiple baseband signals.
